(19) United States
(12) Patent Application Publication
(10) Pub. No.: US 2019/0109034 A1
(43) Pub. Date: Apr. 11, 2019

(54) METHOD AND DEVICE FOR BONDING TWO SUBSTRATES

(71) Applicant: EV Group E. Thallner GmbH, St. Florian am Inn (AT)

(72) Inventor: Andreas Fehkuhrer, Senftenbach (AT)

(73) Assignee: EV Group E. Thallner GmbH, St. Florian am Inn (AT)

(21) Appl. No.: 16/086,762

(22) PCT Filed: Apr. 4, 2017
(86) PCT No.: PCT/EP2017/057969

§ 371 Date: Sep. 20, 2018

(30) Foreign Application Priority Data
Apr. 7, 2016 (DE) 10 2016 106 351.7

(51) Int. Cl. H01L 21/683; H01L 21/67; C09J 5/06

(52) U.S. Cl. CPC H01L 21/6835; H01L 2221/6834; C09J 5/06; H01L 21/67132

(57) ABSTRACT

A method and device for temporarily bonding a product substrate to a carrier substrate. The method includes a) applying a bonding adhesive to the product substrate and/or the carrier substrate to form a bonding adhesive layer having first and second areas; b) connecting the carrier substrate to the product substrate via the bonding adhesive layer; and c) after step b), hardening only the first area of the bonding adhesive layer, wherein the second area of the bonding adhesive layer is not hardened or at least is not substantially hardened.

The invention application describes a method and a device for bonding two substrates.

Especially because provision is made for back-thinning the product wafer during the production process, the back-thinning product wafers have thicknesses of below 100 μm, mostly below 50 μm, today even about 20 μm, in the near future probably between 1 μm and 20 μm. Because of back-thinning with the aid of the carrier wafer, wafers can be made extremely thin, and after back-thinning, further method steps can he carried out by means of standardised processes.

In the semiconductor industry temporary gluing of product wafers to carrier wafers is becoming more and more common. The adhesive, so-called bonding adhesive, is applied to the product wafer and/or the carrier wafer in the form of a coating with as homogenous a coating thickness as possible. After the coating operation however, both wafers must be pressed together at high pressure. This process is known as “bonding.”

A widespread method for attaching a wafer to a glass carrier consists in gluing the glass carrier full-surface to the substrate. The adhesive used is characterised in that, when a certain temperature is exceeded, it loses its adhesive properties. To separate the wafer from the glass carrier, energy is introduced e.g. thermally or by means of a laser, so that the adhesive loses its adhesive properties. A loss of adhesive properties is usually linked to a reduction in viscosity. The substrate and the glass carrier can then be separated from each other.

If during temporary bonding a thermoplastic with a low glass transition temperature T_{g} is used, it may happen that during diverse backside processes the product wafer is subjected to high temperatures and/or or stresses, causing delamination on the rim of the wafer. Polyimides with a low T_{g} (e.g. about 40° C.) are temperature-stable, but at high temperatures viscosity is so low that the bonding adhesive has very little holding power left or that it leaks out of the interface.

Thermoplastics with a high T_{g} such as the HD-3007 polyimide suffer from the disadvantage that they are very difficult to clean and that strong solvents a.o. can attack the passivation of the product wafer.

If cross-linked materials are used as a bonding adhesive these are often very difficult to debond, especially if high structures or unfavourable surface materials are present on the product wafer. Here debonding or cleaning is cumbersome and strong chemicals are often required.

One particular disadvantage with known procedures consists in that the adhesive is destroyed as early as during the backside processes due to the temperatures present, as a result of which the wafer detaches itself from its carrier during these processes. This early detachment of the adhesive may lead to the substrate, i.e. the product wafer being destroyed.

Other known methods employ films which are provided with an adhesive layer. This adhesive also loses its adhesive properties when a certain temperature is exceeded. Just as with the above described methods, the connection between carrier substrate and product substrate may come undone as early as when backside processes are carried out, as a result of the high temperatures occurring.

in order to achieve improved debonding a number of layers are often provided between product substrate and carrier substrate. WO2010/121068A2 for example combines an adhesive layer which can be hardened under UV light and a separating layer which can soften under laser light. Irradiation with a laser changes the chemical-physical properties of the separating layer. Debonding of the product substrate and the carrier substrate is effected via the separating layer. Multi-layer systems however are comparatively expensive to manufacture.

It is therefore the requirement of the present invention to propose a device and a method in order, on the one hand, to achieve maximum bonding power between the substrates at a minimum of cost for all necessary method steps and on the other hand, to permit non-destructive separation of the thin product substrate from the substrate bond after processing the latter. In addition the method steps required for this procedure shall be cost-effective and be possible for the most varied kinds of substrates.

This requirement is met by the subject of the subordinate patent claims. Advantageous further developments of the invention are cited in the sub-claims. The scope of the invention encompasses all combinations of at least two characteristics indicated in the description, the claims and/or the figures. Where value ranges are indicated, all values falling within the said limits shall he deemed disclosed and claimed in any random combination.

The invention relates to a method for temporarily bonding a product substrate to the carrier substrate, comprising the following procedure:
applying a bonding adhesive to the product substrate and/or the carrier substrate for forming a bonding adhesive layer,
connecting the carrier substrate to the product substrate via the bonding adhesive layer,
hardening merely a partial area of the bonding adhesive layer, wherein a remaining area of the bonding adhesive layer is not hardened or at least not substantially hardened.

The invention further relates to a device for temporarily bonding a product substrate to the carrier substrate, comprising:
application means for applying a bonding adhesive to the product substrate and/or the carrier substrate for forming a bonding adhesive layer,
connecting means for connecting the carrier substrate to the product substrate via the bonding adhesive layer,
a hardening device for hardening merely a partial area of the bonding adhesive layer, wherein a remaining area of the bonding adhesive layer is not hardened or at least not substantially hardened.

The method according to the invention/the device according to the invention in particular has the following advantages:
a protective layer exists between product substrate and carrier substrate,
hardening of the bonding adhesive layer can be controlled by section,
an additional anti-adhesive coating is not required. There is no need for reducing the adhesive power by adding an adhesion-reducing layer. This leads to fewer method steps/the product substrate and/or the carrier substrate do not need to be pre-treated.

The bonding adhesive layer may be an adhesive, e.g. a soluble adhesive, in particular a thermoplastic.

Hardening can be performed by electromagnetic radiation, by heat, by current, by magnetic fields and/or by other methods.

Preferably the bonding adhesive layer is applied full-surface onto the product substrate and/or the carrier substrate. This considerably simplifies the manufacturing process allowing throughput to be increased. In addition the bonding adhesive layer provides a filling layer for protecting the structures and for making it easier to detach the carrier substrate from the product substrate.

Alternatively and preferably the bonding adhesive is applied onto only part of the surface of the product substrate and/or the carrier substrate, in particular in a circular-ring-shaped manner to the outer rim of the product substrate and/or the carrier substrate. This has the advantage of simplifying debanding.

If the bonding adhesive layer is applied onto part of the surface, an inner circular-shaped area remains uncoated. Debonding takes place in particular, in a circular-ring-shaped area between the carrier substrate and the product wafer. Areas which are to he hardened may he defined by a mask. Crosslinking takes place, in particular, only in the exposed outer area of the bonding adhesive. The inner area remains unexposed, and therefore any polymerisation in this area is minimal. The bond layer consists, in particular, of two areas with different crosslinking, wherein the polymerised outer circular-ring-shaped area is used for temporary bonding.

Preferably the bonding adhesive is applied to structures of the product substrate. Advantageously this leads to a protection of the structures.

Preferably hardening of the partial area is effected by means of radiation, in particular UV radiation, wherein the hardening equipment may be composed, in particular, of a single radiation source and/or a light source array. in particular a mask is arranged between a radiation source and the substrates for shading the remaining area. in particular, the mask comprises two areas, one area which is permeable to the radiation from the radiation source, and an impermeable area. Alternatively hardening of the partial area is effected through radiation by means of a light source array with adjacently arranged light sources, in particular UV light sources, wherein the light sources can in particular be individually controlled.

Preferably merely an outermost rim area of the bonding adhesive layer is hardened. This makes debonding of the substrates from each other easier.

Preferably an inner remaining area of the bonding adhesive layer is not hardened or at least not substantially hardened. This is the area where the structures of the product substrate may be located so that an improved protection of the structures may be achieved.

At least one of the two, in particular the carrier substrate, may be transparent to electromagnetic radiation of the wavelength range, in which there occurs crosslinking of the bonding adhesive.

According to the invention only that partial area is treated, in which the bonding adhesive is to harden. This will preferably be the peripheral region. The remaining part, in particular the central part, is not treated, therefore no crosslinking or only very minor crosslinking takes place here. This paves the way for using a homogeneous, in particular full-surface, preferably single bond layer, which in particular on the rim, shows its adhesive properties due to hardening and which in particular in the inner area, is used as a filling layer, in particular as a protection for the structures and to facilitate detaching of the carrier substrate from the product substrate.

Advantageously materials with a high glass transition temperature (T_{g}) can be used, because the material solidifies only at the rim and not until crosslinking takes place. Bonding and debonding is possible almost at room temperature.

In the semiconductor industry substrates are understood to mean product substrates or carrier substrates. Substrates are preferably wafers or product wafers. Substrates may have any random shape, but are preferably circular. The diameter of the substrates is in particular industrially standardised. For wafers the industry-standard diameters are: 1 inch, 2 inch, 3 inch, 4 inch, 5 inch, 6 inch, 8 inch, 12 inch and 18 inch. The embodiment according to the invention however, can, in principle, handle any substrate, independently of its diameter. The product substrates may be product substrates which are structured/processed on both sides.

In the ideal case a layer has a homogeneous thickness for the bonding operation according to the invention. In this context, homogeneous thickness means that the thickness of the bonding layer is the same at each position/lies within an acceptable tolerance.

The adhesives/bonding adhesives used may be both thermoplastics with a low glass transition temperature (T_{g}) and thermoplastics with a high glass transition temperature as well as crosslinked polymers. The glass transition temperature is that temperature range, in which the plastic is subject to the biggest change in ductility. Factors such as molar mass, degree of crosslinking, end groups, softeners, crystallinity and. intermolecular forces have an influence on the glass transition temperature.

Plastics can be divided, according to properties, into four main groups: elastomers, thermoplastic elastomers, thermoplastics and duroplastics. Elastomers (lightly crosslinked) thermoplastic elastomers (crosslinked) and duroplastics (strongly crosslinked) consist of cross-linking chain molecules. Thermoplastics, by contrast, are plastics where the macro-molecules consist of linear or branched chains held together merely by inter-molecular forces. The inter-molecular forces weaken under the influence of heat making the thermoplastics pliable and processable. A temporary adhesive is usually a thermoplastic, which softens when the glass transition temperature is exceeded. Substrates glued together with the aid of a thermoplastic, can usually be separated again from each other by heating the thermoplastic above the glass transition temperature.

Bonding adhesives, among others, include epoxy resins (thermally and/or UV crosslinked), photo-resist materials, fluoropolymers, silsesquioxanes, benzocyclobutenes, polymethylmethacrylates, polydimethylsiloxanes, polyaryleneethers, polyetheretherketones, liquid crystalline polymers and thermoplastic copolymers such as poly vinylidenchloride.

Temporary fixing is easy, quickly accomplished, cost-effective, efficient, reversible as well as physically and chemically stable. Most frequently the carrier wafers are coated with a bonding adhesive and bonded to the product wafer by a bonding method. The adhesive layer can be applied over the entire surface of the carrier wafer and/or the product wafer. The temporary bond produced in this way is resistant to high-temperatures and strong forces. Furthermore further processing steps are performed on the second side if required, such as producing bumps and/or bump groups and/or other connection layers and/or electrical conductor tracks and/or attaching chips. It would also be feasible to change the side on which the product substrate is to he processed by bonding a second carrier wafer temporarily to the free side and then removing the first carrier wafer.

Hardening of the adhesive layer, depending on the material, is preferably effected by electromagnetic radiation, preferably by UV light or IR light. Electromagnetic radiation has a wavelength in the range between 10 nm and 2000 nm, preferably between 10 nm and 1.500 nm, more preferably between 10 nm and 1000 nm, most preferably between 10 nm and 500 nm, at the very most preferably between 10 nm and 400 nm.

Thermal hardening is also possible. Thermal hardening is effected between 0° C. and 500° C., preferably between 0° C. and 400° C., even more preferably between 0° C. and 300° C., most preferably between 0° C. and 200° C.

More commonly hardening can be effected by electromagnetic radiation, by heat, by current, by magnetic fields or other methods. Hardening, according to the invention, is preferably based on polymerisation of the basic material. Polymerisation is then started using a so-called initiator. If electromagnetic radiation is used for hardening, at least one of the two substrates, in particular the carrier wafer, is transparent to electromagnetic radiation in the wavelength range, in which crosslinking of the bonding adhesive happens. Therefore the carrier wafer, in particular, is a glass or sapphire wafer.

Up to a certain temperature range the adhesive layer possesses adhesive properties (non-detachable connection) which are sufficient for achieving satisfactory fixing of the substrates. The adhesive properties are described via the physical magnitude of the adhesion. Adhesion is preferably defined by the energy per unit of area, which is necessary for separating two connected surfaces from each other. Energy is quoted in J/m². A typical empirically measured mean value of energy per unit of area, between pure silicone and a polymer, is approx. 1.2 J/m². Respective values may fluctuate depending on the coating material, substrate material and contamination, in this case a polymer. In future much more efficient coating materials are to be expected. The energy per unit of area is greater than 0.00001 J/m², preferably greater than 0.0001 J/m², more preferably greater than 0.001 J/m², most preferably greater than 0.1 J/m², at the very most preferably greater than 1 J/m².

In order to separate these two substrates, they are e.g. heated above this temperature range, as a result of which the adhesive loses its adhesive properties and the two wafers, carrier wafer and product wafer, are then separated by introducing a horizontal and/or vertical force. At high temperatures thermal disintegration of the polymers is generally to be expected. If thermoplastics are used, heating up to just above the glass transition temperature is sufficient.

Additionally the rim zones may be physically and/or chemically and/or thermo-mechanically and/or mechanically treated as appropriate in order for the temporary bond to lose its adhesion.

Or the adhesive layer may be applied only to the rim of the product wafer and/or the carrier wafer. The inner area does not necessarily include an adhesive layer. The layer of the inner area may have random properties, but is usually introduced as a support into the gaps of individual structures such as the bumps.

The separating procedure is similar to the separating procedure of a full-surface bond, although only the rim zones have to be treated physically and/or chemically, as appropriate, to make the temporary bond lose its adhesion. Accompanying effects are lower temperatures, lower process times, and a decrease in consumption of chemical materials.

Innumerable further methods exist for undoing a temporary bond, e.g. by using special lasers and using an additional separating layer, or by using carrier wafers with small diameter holes, through which a suitable solvent is introduced full-surface into the bond. Furthermore the destruction or split of the rim zone can be performed by means of laser, plasma etching, water jet or solvent jet.

The bonding adhesive can be irradiated in particular through a glass substrate. In order to avoid uniform radiation, a mask and/or a coated glass carrier are required. To this end a glass substrate for example is coated with a film, which comprises permeable and impermeable areas. The coating may be permanent or temporary. If the coating is temporary, the film can be removed again from the glass substrate. The glass carrier thus remains part of the carrier substrate-product substrate bond and may be utilised in further method steps as required. Alternatively a mask is used in addition to the carrier substrate. According to the invention the mask, among others, can also consist of a glass carrier having impermeable areas applied thereon. The light-sensitive bonding adhesive is exposed to UV light, wherein the areas which are to be hardened, are defined by the mask. The mask is used to shade areas which are not be exposed.

A chuck, in particular a spinner chuck, is particularly suited as a means for receiving the carrier-substrate-product-substrate bond, in particular using under-pressure, e.g. suction webs, bores and/or suction cups. Alternatively it is feasible to use an electrostatic holder and/or a mechanical holder, e.g. in the form of lateral clamps.

With a further advantageous embodiment of the invention provision is made for using a multi-part aperture instead of a mask in order to selectively expose selected areas of the stack surface, specifically the rim.

With an alternative embodiment of the invention provision is made for the light source for hardening the adhesive layer to include many adjacently arranged UV light sources, which in particular can be individually controlled. By using such an array of UV light sources, which in particular can be individually controlled, the UV light can irradiate selectively selected areas of the stack surface, specifically on the rim. For this reason this embodiment does not require a mask.

Debonding after processing the product substrate is effected in that initially the hardened, completely crosslinked bonding adhesive on the rim is detached, in particular chemically and/or mechanically. The radiation dose during hardening must be chosen such that the partially crosslinked area can again be separated using slide-off/lift-off (with or without temperature).

With one advantageous embodiment of the invention provision is made for means for releasing the connection comprising a fluid agent, in particular a solvent selectively dissolving the connection layer, for dissolving the connection layer. Dissolving the connection layer chemically is particularly gentle for the substrates, and if an appropriate material is chosen, dissolving can be carried out very quickly, in particular if only rim areas of the substrates are provided with a connection layer, so that the solvent can act quickly from the side. In this way there is no need for perforations in the carrier substrate and/or product substrate.

With a further advantageous embodiment of the invention provision is made, for the purpose of separating the product substrate and carrier substrate that the in particular ring-shaped, crosslinked part of the adhesive layer is heated to a predefined temperature. At this temperature the adhesive, such as a thermoplastic, loses its adhesive properties, so that it is possible to detach the product substrate from the carrier substrate. Care should be taken to apply heat exclusively in the area of the, in particular ring-shaped, crosslinked (in particular outer) adhesive layer, in order not to damage any structures of the product substrate. A heating element with a ring-shaped heating section is particularly suitable for heating the adhesive layer. Alternatively the bond layer may be heated locally by laser light, which may be of advantage, in particular where the bond layer is ring-shaped.

With an alternative embodiment of the invention provision is made for the means for releasing the connection comprising mechanical separating means, in particular a blade for cutting through the connection layer, for detaching the connection layer. This makes it possible to separate the product substrate from the carrier especially quickly. A combination of mechanical separating means and fluid means is also possible. The device for separating the product substrate from the carrier substrate is described in the patent specification EP2402981B1. EP2402981B1 describes a device and a method for detaching a wafer from a carrier. The separation/the separating device is performed in accordance with EP2402981B1 and is not described in detail.

In the ideal case the carrier substrate and product substrate should then be able to be separated from each other because the bonding adhesive has not been crosslinked, in particular in the centre. Otherwise a slide-off debond may have to be carried out. The publication DE102009018156A1 describes a device/a method for separating a substrate from a carrier substrate connected to the substrate by a connection layer, where the separation of the substrate is carried out by performing a parallel shift of substrate and carrier substrate in relation to each other (slide-off). The publication WO2013/120648 describes a method, where detaching is performed by applying a traction force (lift-off).

Generally speaking combinations of chemical, thermal, mechanical and optical method steps can be used for detaching the bond layer.

With a further advantageous embodiment of the invention a material is used for the adhesive layer, which changes the aggregate state at different wavelengths. Such light-controlled adhesive materials are described for example in the publication US 2015/0159058A1, in which a fluid-crystalline polymer is used. In this embodiment the light-controlled adhesive is advantageously applied during rotation of the carrier substrate or the product substrate and distributed evenly and homogeneously due to the rotation of the substrate.

Alternatively the light-controlled adhesive is not applied full-surface between carrier substrate and product substrate, but applied exclusively in a ring-shape in the rim area between product substrate and carrier substrate. Bonding is carried out with the adhesive in a liquid state. Following its application, exposure to light (with or without mask depending on the requirement) is effected at the required wavelength. At the wavelength λ₁/the wavelength range Δλ₁ the adhesive solidifies. Following processing of the back side from the product stack exposure is effected at the second wavelength λ₂/the second wavelength range Δλ₂, so that the adhesive liquefies again and debanding by slide-off or lift-off is possible.

The invention may be applied in combination with established industrial coating methods, such as spin coating methods or spray coating methods. If a bonding adhesive is used, which is specific to selective UV-controlled spatial hardening, the manufacturing process is much simplified since only one bond layer has to be applied full-surface. Thus coating of the substrate is quick, full-surface and standardised, which is advantageous to the throughput. Furthermore there is no need for pre-treating substrate or carrier substrate surfaces because no further coatings are required (such as an anti-adhesion layer or a separating layer).

Based on the present invention repeated use of the carrier substrate is possible without having to clean the same by performing cumbersome and expensive cleaning processes. Insofar as during debanding any residual bonding adhesive remains on the product substrate or carrier substrate, this can be removed by a cleaning step.

Further advantages, features and details of the invention are revealed in the description below of preferred embodiments as well as in the drawings, in which

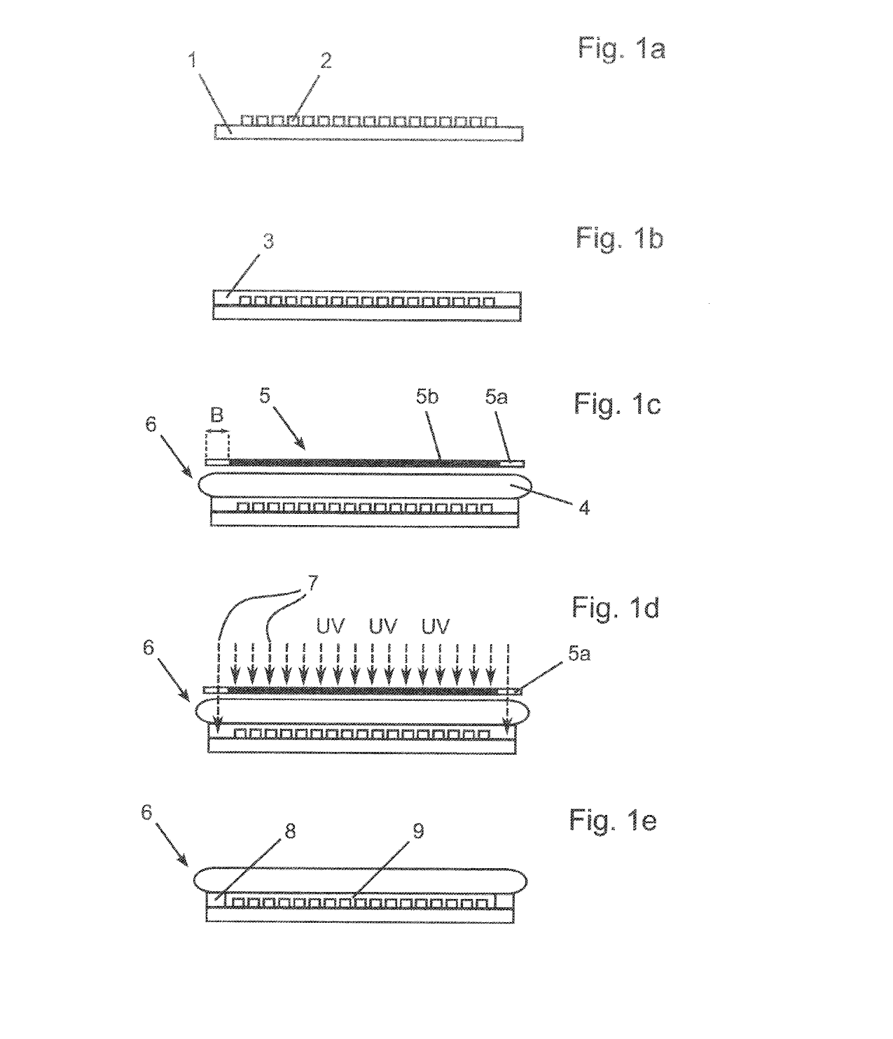

FIG. 1a shows a cross-sectional view of a product substrate with structures,

FIG. 1b shows a cross-sectional view of the product substrate after applying a bonding adhesive layer,

FIG. 1c shows a cross-sectional view of a product-substrate-carrier-substrate stack with an exposure mask,

FIG. 1d shows a further cross-sectional view of the product-substrate—carrier-substrate stack,

FIG. 1e shows a further cross-sectional view of the product-substrate-carrier-substrate stack after temporary bonding,

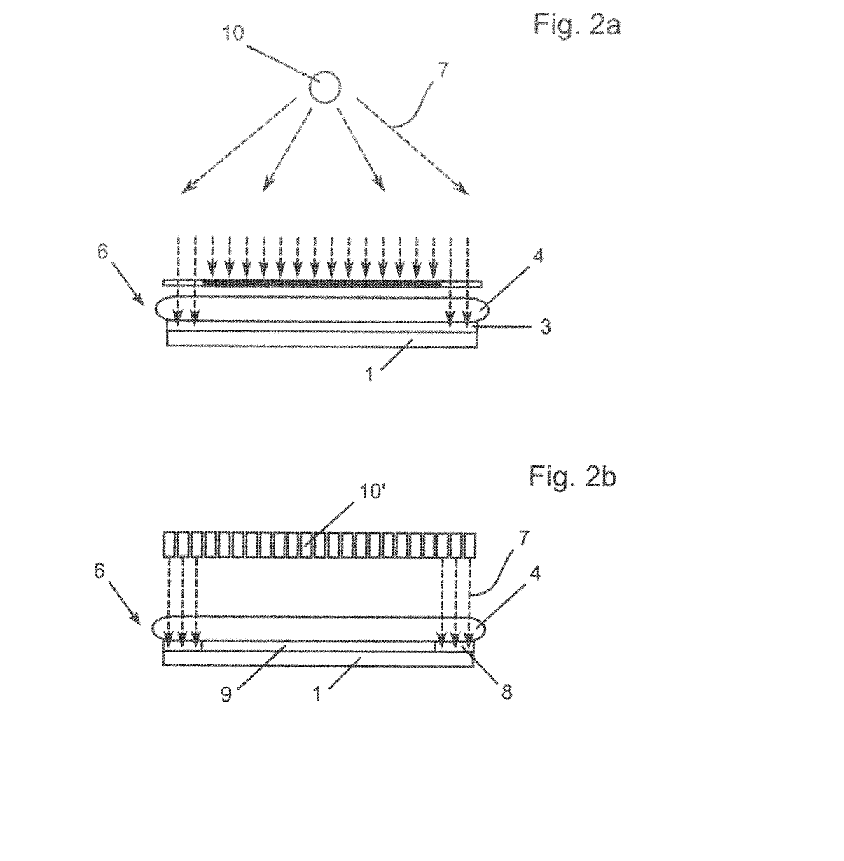

FIG. 2a shows a further cross-sectional view of the product-substrate-carrier-substrate stack and a UV source,

FIG. 2b shows a further cross-sectional view of the product-substrate-carrier-substrate stack and a UV light source array,

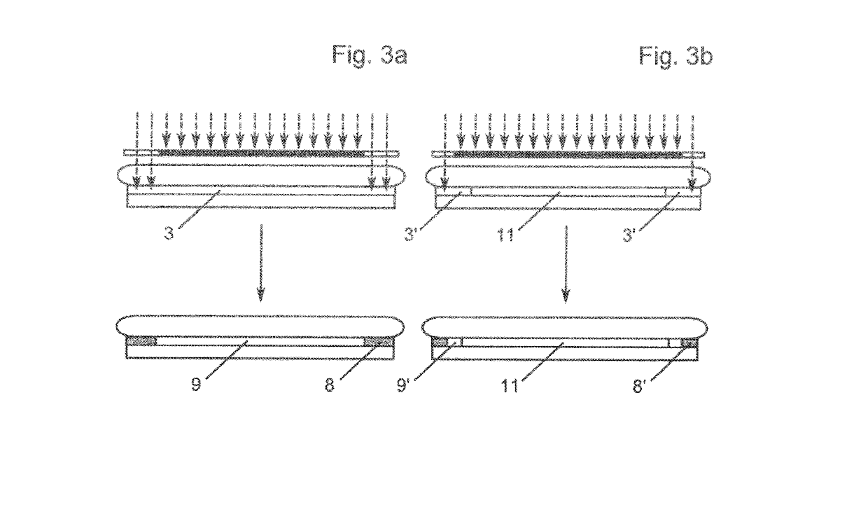

FIG. 3a shows a further cross-sectional view of the product-substrate-carrier-substrate stack with a bonding adhesive layer applied full-surface,

FIG. 3b shows a further cross-sectional view of the product-substrate-carrier-substrate stack with a bonding adhesive layer applied over part of the surface.

Identical components or components having the same function are marked with identical reference symbols.

FIGS. 1a-1e describe an exemplary inventive procedure for temporarily bonding a product substrate 1 provided with structures to a carrier substrate 4. The process is carried out, in particular, in a bonding chamber not shown. The structures 2 may e.g. he solder balls or chips forming a topography (see FIG. 1a). It is also feasible for the product substrate 1 not having a topography, either because no structures 2 are present or because the structures 2 are directly formed in the product substrate 1.

According to FIG. 1b the bonding adhesive layer 3 has been applied full-surface to the structures 2, which lie in and/or on the product substrate 1. The layer thickness of the coating is adapted to match the topography and in particular lies between 1 μm and 15 mm, preferably between 10 μm and 10 mm, more preferably between 50 μm and 10 mm, most preferably between 100 μm and 5 mm. A substrate receiving means (not shown) permits handling of the substrate with a liquid layer applied to it.

The liquid layer in particular is a liquid thermoplastic, which is present in the so-called interface during contact-making with the carrier wafer. The solvent concentration of the liquid layer lies, in particular, between 0 and 80%, preferably between 0 and 65%, more preferably between 0 and 50%. The layer thickness depends, among others, also on the viscosity of the solution. The viscosity is a physical property, which is strongly temperature-dependent. This generally decreases as the temperature increases. At room temperature viscosity lies between 10⁶ Pa*s and 1 mPa*s, preferably between 10⁵ Pa*s and 1 Pa*s, more preferably between 10⁴ Pa*s and 1 Pa*s, most preferably between 10³ Pa*s and 1 Pa*s.

After coating the product wafer 1 with the bonding adhesive 3 according to FIG. 1b, the product wafer is bonded to the carrier substrate 4 in a temporary bonding procedure by aligning, contacting and bonding. The expert in this field will be familiar with temporary bonding technologies.

According to FIGS. 1c and 1d the bonding adhesive layer 3 is exposed to light, in particular UV light, through a mask 5. The areas to be hardened are specified by the mask 5. The mask 5 may be shaped at random, and is preferably round, rectangular or square, more preferably it may be in the format of the carrier substrate, most preferably it may follow the standard formats used in lithography. The diameter of the mask 5 preferably substantially matches the diameter of the carrier substrate 4. The mask 5 is then approximately the size of the carrier substrate and consists of permeable areas 5a and impermeable areas 5b for the selected light wavelength range. Alternatively the mask used may be a coated glass carrier. The mask 5 shown in FIGS. 1c and 1d was manufactured such that an inner circular area 5b of the mask 5 is impermeable to light and an outer circular-ring area 5a of the mask 5 is permeable to light. The outer circular-ring area 5a has a ring width B. Exposure of the bonding adhesive layer 3 may be effected through the carrier substrate and/or through the product wafer 1. The decisive factor, above all, is the transparency of the respectively irradiated substrate/wafer for the respectively used electromagnetic radiation.

Alternatively the adhesive used may consist of other materials, which depending on properties are employed as positive or negative adhesives and which require a respectively adapted exposure mask. A negative adhesive polymerises when exposed, whilst a positive adhesive as a result of exposure becomes soluble again for respective solvents/loses its adhesive properties.

FIG. 1d shows that the stack 6 is exposed to UV light through the mask 5. Using the mask 5, only the outer circular area 5a is permeable to the UV light. According to FIG. 1e only the exposed outer area 8 of the layer 3 is crosslinked. The inner area 9 remains unexposed and as a result, there is no polymerisation in this area. The bond layer 3 in this embodiment as per figure le consists of two areas 8 and 9, which are crosslinked differently, wherein the polymerised outer circular-ring-shaped area 8 is used for temporary bonding, and the non-polymerised or less polymerised inner circular-shaped area 9 is used for embedding the structures 2. The ring width B of the outer area 8 is between 0 and 30 mm, preferably between 0.1 and 20 mm, more preferably between 0.25 and 10 mm, most preferably between 0.5 and 5 mm.

The method according to the invention thus shifts the strongly adhesive and less adhesive zones, which according to the state of the art must be manufactured during a number of process steps, into the bond layer. As a result, there is then no longer any need for surface-treating the substrates, e.g. applying an anti-adhesive coating. Dissolving (debonding) takes place in the circular-ring-shaped area 8 between carrier substrate and product wafer.

According to the two exemplary embodiments in FIGS. 2a and 2b at least one UV light source 10, 10′ is used. The usually non-directional emission from the UV light source 10 (see FIG. 2a) is directed at the stack 6, e.g. by reflectors and/or by a lens system (not shown). The aim is to achieve as homogenous a distribution of the radiation across the stack 6 as possible. The UV light 7 used is optionally broad-band light or is specially adapted to suit the photo initiator used in the bonding adhesive layer 3. The wavelength range of the UV hardening material 3 in particular lies between 50 nm and 1000 nm, preferably between 150 nm and 500 nm, more preferably between 200 nm and 450 nm. The mask 5 is used to define the areas 8 which are to be exposed.

In an alternative embodiment according to FIG. 2b an array of UV light sources 10′ is used, wherein the UV light sources 10′ are preferably individually controlled. The light source array 10′ can be guided directly to the substrate-carrier-substrate stack 6, or light conductors may be used, so that the light sources 10′ may reside outside the bonding chamber. The bonding adhesive 3 in this embodiment is applied full-surface onto the carrier 4 and/or product wafer 1. The carrier wafer and product wafer are then bonded. One of the two, in particular the carrier wafer 4, is transparent to electromagnetic radiation of the wavelength range in which crosslinking of the bonding adhesive 3 occurs. By selectively controlling the UV light sources 10′ of the array, only that partial area 8 is exposed, in which the bonding adhesive 3 is to harden. That is preferably the peripheral region 8. The remaining, in particular central part 9 is not irradiated and therefore no crosslinking occurs here. If the material used as a bonding adhesive 3 is a material which changes the aggregate state for different wavelengths, exposure following processing is effected at a second wavelength λ₂ or a second wavelength range Δλ₂, so that the bonding adhesive liquefies again and debonding is possible.

According to FIGS. 3a and 3b the bonding adhesive layer may be applied full-surface 3 or part-surface 3′. If the bonding adhesive layer is applied part-surface, the inner circular area 11 is not exposed. Debonding in FIG. 3a takes place in the circular-ring shaped area 8 between the carrier substrate and the product wafer. Analogously in FIG. 3b debonding takes place in the circular-ring shaped area 8′ between the carrier substrate and the product wafer. Again the areas to be hardened are defined by a mask 5. According to FIG. 3b crosslinking only takes place in the exposed outer area 8′ of layer 3′. The inner area 9′ remains unexposed, and therefore there is in essence no polymerisation in this area. The bonding layer 3′ in this embodiment according to FIG. 3b consists of two areas 8′ and 9′, in which crosslinking varies, wherein the polymerised circular-ring shaped area 8′ is used for temporary bonding.

The embodiments described above have in common that the bond layer 3, after hardening, consists of a heterogeneous layer. This bond layer 3 is to harden in particular on the rim. The remaining, in particular central part, is not irradiated and therefore there occurs no or very little crosslinking in this area. There is therefore no need for surface treatment steps or additional layers such as separating layers. This leads to quicker as well as more simplified temporary bonding processes. Temporary fixing is thus simple, quickly realised, cost-effective, efficient, reversible as well as physically and chemically stable. Due to effecting fixing in the rim area, the connection between the carrier wafer and the product wafer, following the production steps, can be simply and quickly undone by chemical and/or mechanical means.

In order to reduce defects, applying the bonding adhesive 3 and temporary bonding can be carried in a vacuum and/or in an inert gas atmosphere. Performing the working steps in an inert gas atmosphere can lead to advantages such as better chemical resistance, fewer defects and quicker UV hardening. Furthermore any gas inclusions occurring in an inert gas atmosphere can be substantially avoided or excluded. Alternatively the entire work space can be acted upon by an inert gas and/or, via a vacuum device, by a vacuum as a defined atmosphere.

### LIST OF REFERENCE SYMBOLS

1 product substrate
2 structure
3, 3′ bonding adhesive
4 carrier substrate
5 mask
5a permeable area
5b impermeable area
6 stack
7 UV light
8, 8′ outer area
9, 9′ inner area
10, 10′ UV light source
11 non-exposed area
B ring width

1-14. (canceled)

15. A method for temporarily bonding a product substrate to a carrier substrate, said method comprising:
a) applying a bonding adhesive to the product substrate and/or the carrier substrate to form a bonding adhesive layer having first and second areas;
b) connecting the carrier substrate to the product substrate via the bonding adhesive layer; and
c) after step b), hardening only the first area of the bonding adhesive layer, wherein the second area of the bonding adhesive layer is not hardened or is at least not substantially hardened.

16. The method according to claim 15, wherein the bonding adhesive is applied onto a full surface of the product substrate and/or the carrier substrate.

17. The method according to claim 15, wherein the bonding adhesive is applied onto a partial surface of the product substrate and/or the carrier substrate.

18. The method according to claim 17, wherein the partial surface of the product substrate and/or the carrier substrate is a circular-ring shaped surface at an outer rim of the product substrate and/or the carrier substrate.

19. The method according to claim 15, wherein the bonding adhesive is applied to structures of the product substrate.

20. The method according to claim 15, wherein hardening of the first area of the bonding adhesive layer is effected by means of irradiation.

21. The method according to claim 20, wherein the means of irradiation is UV irradiation.

22. The method according to claim 15, wherein the method further comprises arranging a mask between a radiation source and the product and carrier substrates for shading the second area.

23. The method according to claim 15, wherein hardening of the first area is effected by irradiation by means a light source array with adjacently arranged light sources.

24. The method according to claim 23, wherein the light sources are UV light sources.

25. The method according to claim 23, wherein the light sources are controlled individually.

26. The method according to claim 15, wherein the first area of the bonding adhesive layer is an outermost rim area, and only said outermost rim area of the bonding adhesive layer is hardened.

27. The method according to claim 15, wherein the second area of the bonding adhesive layer is an inner area located inside of the first area, and said inner area of the bonding adhesive layer is not hardened or is at least not substantially hardened.

28. A device for temporarily bonding a product substrate to a carrier substrate, said device comprising:
a) application means for applying a bonding adhesive to the product substrate and/or the carrier substrate to form a bonding adhesive layer, said bonding adhesive layer having first and second areas;
b) connecting means for connecting the carrier substrate to the product substrate via the bonding adhesive layer;
c) a hardening device for hardening only the first area of the bonding adhesive layer after connecting the carrier substrate to the product substrate, wherein the second area of the bonding adhesive layer is not hardened or is at least not substantially hardened.

29. The device according to claim 28, wherein the hardening device comprises a radiation source.

30. The device according to claim 29, wherein the radiation source is a UV light source.

31. The device according to claim 29, further comprising a mask arranged between the radiation source and the product and carrier substrates for shading the second area of the bonding adhesive layer.

32. The device according to claim 31, wherein the mask comprises an area permeable to radiation of the radiation source and an impermeable area.

33. The device according to claim 28, wherein the hardening device comprises a light source array with adjacently arranged light sources.

34. The device according to claim 33, wherein the light sources are individually controllable light sources.
